(19) United States
(12) Patent Application Publication
(10) Pub. No.: US 2026/0353736 A1
(43) Pub. Date: Nov. 5, 2026

(54) (Al)Ga2O3/(Mg)NiO Ternary Heterojunctions for electronic and optoelectronic applications

(71) Applicants: David ROGERS, Sainte Savine (FR); Ferechteh HOSSEINI-TEHERANI, Orsay (FR); Philippe Henri BOVE, Gif sur yvette (FR); Eric Vinod SANDANA, Garges-Lès-Gonesse (FR)

(72) Inventors: David ROGERS, Sainte Savine (FR); Ferechteh HOSSEINI-TEHERANI, Orsay (FR); Philippe Henri BOVE, Gif sur yvette (FR); Eric Vinod SANDANA, Garges-Lès-Gonesse (FR)

(21) Appl. No.: 18/439,763

(22) Filed: Feb. 12, 2024

(30) Foreign Application Priority Data
Feb. 12, 2023 (FR) 2301291

(51) Int. Cl. H10D 62/82; H10D 8/50; H10F 10/17

(52) U.S. Cl. CPC H10D 62/8271; H10D 8/50; H10F 10/17

(57) ABSTRACT

Vertical heterojunction bipolar or PIN diode based on heterostructures between ternary alloys (Mg)NiO and (Al)Ga2O3 or (Mg)NiO/i-MgO/(Al)Ga2O3 or (Mg)NiO/Al2O3/(Al)Ga2O3) characterized in that the (Mg)NiO being p-type, the (Al)Ga2O3 being n-type and the intrinsic layer being MgO or Al2O3, and that the bandgaps of Ga2O3 and NiO have been increased by alloys with Al and/or Mg to appropriately design the alignment of said bandgaps and to optimize carrier injection to enable more efficient diode operation, operation of a photodetector at shorter wavelengths, and operation of power electronics at higher voltages..

### TECHNICAL FIELD OF THE INVENTION

This invention proposes new (Mg)NiO/(Al)Ga2O3 p-n heterojunction diodes to be used in high-power electronics and UVC photodetectors, as well as a method to manufacture them. The inventive nature is related both to the new concept of exploiting the semiconductor potential of these oxide materials and to the innovative method for manufacturing them.

About half of the energy consumed worldwide is in the form of electricity [1], and over 30% of our electricity supply goes through power electronics (PE) components [2]. The vast majority of currently used electronic components are silicon-based. However, these are limited in power and have high “on-resistances” for high voltage operation, thus leading to significant irreversible losses. To address these issues, a second generation of wide bandgap (WBG) semiconductor-based power electronics (PE) such as SIC and GaN has been developed over the past decades. However, the substrates and/or active layers of both materials are produced by energy-intensive techniques and are still very expensive [3].

Additionally, ultraviolet (UV) photodetectors (PD) are emerging for applications such as flame/spark detection, chemical/biological agent detection, military countermeasures, environmental monitoring, sterilization monitoring, line-of-sight-free detection, UV space communications, and astronomy [1-4]. To minimize false alarms and background clutter, many of these devices operate in the UVC part of the solar spectrum (SB) below 290 nm (<290 nm). Most current photodetectors (PD) use photomultipliers (PM). These are based on vacuum tubes, which are bulky, fragile (mechanically and electrically), expensive, and require high operating voltages. Semiconductor “Solar Blind” photodetectors, based on quantum transitions in semiconductors, are much more robust than photomultipliers (PM) and promise both size and cost advantages over photomultipliers (PM). They also have the potential for higher quantum efficiency, intrinsic spectral range selectivity, extended lifetimes, lower noise, and lower power requirements.

Silicon photodiodes have been used for UV detection for a long time. Although they work well, their bandgap is relatively small, so they respond equally well to visible spectrum as to UV signals and require optical filters to either be visible or solar blind. However, a class of materials called “wide bandgap semiconductors (WBG)” is naturally solar-blind. FIG. 1 contrasts the wavelength operating range that can be achieved for current WBG optosemiconductors. Silicon carbide (SiC), with a room temperature bandgap of 2.4 to 3.1 eV, was the first WBG semiconductor commercially adopted as UVC PD (e.g., in flame detectors) [5]. However, SIC's bandgap is not high enough to be intrinsically solar-blind, and bandgap engineering through alloying is not possible. Thus, the insertion of optical filters is still necessary to tune photodetection to the UVC range. Gallium nitride (GaN), on the other hand, has a bandgap that is adjustable from the near to far UV range through alloying with aluminum, and (Al)GaN-based devices have been widely explored for direct UV light detection in the SB range [6-8]. However, this materials system suffers from several key issues: high dislocation densities, low conductivity, and lattice mismatches/thermal expansion (with conventional sapphire substrates) leading to cracking and efficiency drop with increasing Al content. As a result, there has been limited success in demonstrating solar-blind (SBPD) photodetectors based on (Al)GaN with both low background signals and good quantum efficiencies for wavelengths below 250 nm [9,10]. (Mg)ZnO is based on wurtzite ZnO, which has a wide direct bandgap of ~3.4 eV that can be tuned into the solar spectrum SB range by alloying with MgO (e.g., ~7.8 eV) [11]. Mg ion has a similar radius to Zn [12], so there are fewer problems with strain loss and efficiency than for (Al)GaN. However, as the Mg content increases, the hexagonal close-packed (hcp) ZnO phase transforms into cubic face-centered (fcc) MgO, which is much more insulating in nature and less suited to device applications. Thus, SB operation is limited to an upper range of about 250 nm.

Although boron nitride (BN) and diamond (D) have intrinsic “ultra-wide bandgaps” (UWBG) (of 6.1 and 5.5 eV, respectively) which are very attractive for SB operation [13,14], they are difficult to develop as large-area thin films with high crystalline quality and low defect densities. Like SIC, they also have limited scope for further bandgap engineering into the UV. Therefore, there is a need for a more suitable semiconductor system for wavelength-selective detection in the UVC range of 200 to 250 nm.

### PRIOR ART

Recently, a highly promising third generation of power electronics (PE) and photodetectors (PD) based on WBG Ga2O3 (Eg=4.9 eV, which can be enhanced by the addition of Al [4]) has emerged [5]. This stems from the discovery of n-type doping in Ga2O3 material that was previously considered an insulator. Consequently, there has been increased research & development (R&D) focused on communication/amplification power electronics based on β-Ga2O3 and UVC photodetection [6] (mainly in the United States, Asia, and Germany). Power electronic (PE) application is also founded on the potential of much lower on-state resistance accompanied by breakdown (~8 MV/cm) and Baliga figure of merit (~1 GW/cm2) that significantly surpasses those of Si, GaN, or SIC [5]. Many standard thin film growth techniques have been adopted for Ga2O3-based device fabrication (e.g., MBE, ALD, MOCVD, HVPE) [13], [14] & NiO [15]. Since shallow p-type dopants are not available or very ineffective to date for Ga2O3 [7], bipolar devices with homojunction Ga2O3 are not feasible. Indeed, the use of p-n junction architectures, such as those used in GaN-based devices.

For power electronics, this is a key factor limiting the potential for reducing on-state resistance while maintaining high breakdown field (Vbr). Thus, p-type doping capability is of utmost importance in the quest for ultimate performance.

Similarly, the range of possibilities with Ga2O3-based UVC sensors is also limited by the lack of availability of p-n homojunctions. For example, they are limited in their autonomy as they require bias voltage to operate, unlike p-n junction devices operating in photovoltaic mode.

However, it is generally agreed that useful levels of majority shallow acceptor doping (p-type) in β-Ga2O3 are unlikely to be achieved due to a combination of factors, including the relatively low absolute energy level of the valence band, the absence of an identified shallow acceptor, the relatively high hole effective masses at the top of the valence band, the propensity for hole self-trapping, and the relatively low energy of formation of oxygen donor background (which compensates acceptors) [139, 148, 195]. Nevertheless, there are several reports of relatively resistive layers with predominantly p-type doping in nominally undoped [196, 197], H-doped [198], and N-doped [199] β-Ga2O3. In the latter case, lateral p-type β-Ga2O3 MOSFETs have been reported. The absence of a low-resistance p-type layer for the anode has so far prevented the demonstration of a p-n homojunction-Ga2O3 diode, but p-n heterojunction diodes have been achieved by integrating n-type Ga2O3 with p-type semiconductors such as Cu2O [200] and NiO [201-204]. With a bandgap of 3.7 eV, NiO is the complementary p-type oxide of choice due to its robustness and flexible dopability. [9].

The state of the art in the literature uses binary semiconductors (e.g., n-Ga2O3 and p-NiO) to form the heterojunction.

### INVENTION DISCLOSURE

This invention proposes heterojunctions of new ternary wide bandgap semiconductor materials/(Al)Ga2O3/(Mg)NiO heterojunctions. Alloying with Al and Mg [8], respectively, is introduced to adjust the bandgaps of Ga2O3 and NiO. This shows that (i) these ternary compounds have a much larger and more tunable set of properties than binaries (ii) power electronics is a quest for higher bandgap materials that are more robust/tunable.

The invention proposes a bipolar diode or PIN at vertical heterojunction based on heterostructures between the ternary alloys (Mg)NiO and (Al)Ga2O3 or (Mg)NiO/i-MgO/(Al)Ga2O3 or (Mg)NiO/Al2O3/(Al)Ga2O3). The diode is characterized in that the (Mg)NiO is of p-type, the (Al)Ga2O3 is of n-type, and the intrinsic layer is either MgO or Al2O3. The bandgaps of Ga2O3 and NiO have been increased by alloys with Al and Mg, respectively, in order to appropriately design the alignment of said bandgaps and optimize carrier injection to enable more efficient operation of the bipolar diode, or operation of a photodetector at shorter wavelengths, or operation of power electronics at higher voltages.

According to particular features, in the bipolar diode or PIN at vertical heterojunction based on heterostructures (Mg)NiO/(Al)Ga2O3 or (Mg)NiO/i-MgO/(Al)Ga2O3 or (Mg)NiO/Al2O3/(Al)Ga2O3, the n-AlGa2O3 is doped with shallow impurities, using Si or Sn, and p-MgNiO is doped with shallow impurities using Li in order to design the carrier concentration and Fermi level for more efficient and enhanced bandgap alignment and carrier injection.

According to particular features, in the bipolar diode or PIN at vertical heterojunction based on heterostructures (Mg)NiO/(Al)Ga2O3 or (Mg)NiO/i-MgO/(Al)Ga2O3 or (Mg)NiO/i-Al2O3/(Al)Ga2O3, custom and controlled growth of continuous 2D MgO layers with i-doping allows for managing the internal electric field.

According to particular features, in the bipolar diode or PIN at vertical heterojunction based on heterostructures (Mg)NiO/MgO/(Al)Ga2O3 or (Mg)NiO/i-MgO/(Al)Ga2O3 or (Mg)NiO/Al2O3/(Al)Ga2O3, growth of n-type (Al)Ga2O3, p-type (Mg)NiO, and intrinsic MgO and Al2O3 layers is performed by epitaxy, namely: molecular beam epitaxy (MBE) or atomic layer epitaxy (ALD) or metalorganic chemical vapor deposition (MOCVD) or hydride vapor phase epitaxy (HVPE) or cathodic sputtering deposition (diode and rf) or pulsed laser deposition (PLD) or electron beam (or ion) beam deposition.

According to particular features, in the bipolar diode or PIN at vertical heterojunction based on heterostructures (Mg)NiO/(Al)Ga2O3 (or (Mg)NiO/i-MgO/(Al)Ga2O3 or (Mg)NiO/Al2O3/(Al)Ga2O3, the adapted and controlled growth of n-type doping of (Al)Ga2O3, and p-type doping of (Mg)NiO is in the range of 1014 to 1020/cm-3 in order to optimize component performance and allow for management of the internal electric field.

According to particular features, in the bipolar diode or PIN at vertical heterojunction based on heterostructures (Mg)NiO/(Al)Ga2O3 or (Mg)NiO/i-MgO/(Al)Ga2O3 or (Mg)NiO/Al2O3/(Al)Ga2O3, electrical properties can be adjusted by in situ doping control, via oxygen stoichiometry and/or doping with Sn, Si, Li, and/or by post-treatments through irradiation and/or thermal treatment.

According to particular features, in the bipolar diode or PIN at vertical heterojunction based on heterostructures (Mg)NiO/(Al)Ga2O3 or (Mg)NiO/i-MgO/(Al)Ga2O3 or (Mg)NiO/Al2O3/(Al)Ga2O3, the properties of each layer and the interfaces between layers, including crystalline structure, composition, thickness, conductivity, mobility, band alignment, and doping level, are designed to provide suitable P-N heterojunction behavior for power electronics or UVC photodetection.

### BRIEF DESCRIPTION OF THE FIGURES

FIG. 1 PN & PIN heterojunctions based on (Mg)NiO (p-type)/MgO (I)/(Al)Ga2O3 (n-type).

### DETAILED DESCRIPTION OF THE DRAWINGS

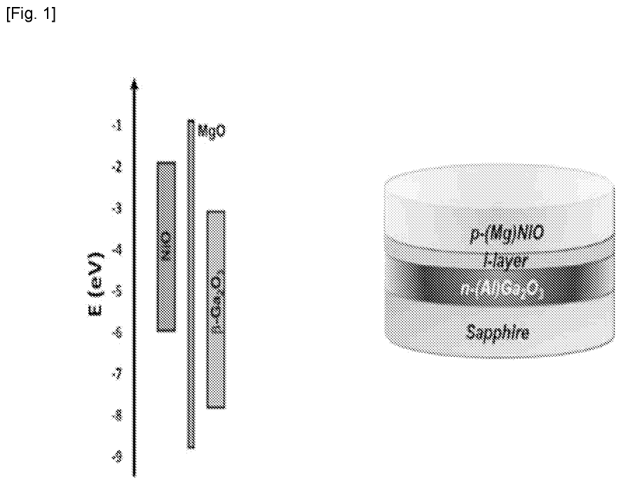

FIG. 1 illustrates a band alignment and schematic of a p-i-n junction formed using n-doped (Al)Ga2O3 and p-doped (Mg)NiO with an intrinsic MgO intermediate layer.

The nature of the minority carriers in these devices should allow for lower forward-state resistances and consequently, offer better performance in the forward-state and an improved range of functionalities. The vertical architecture will also bring about reductions in the current footprint and a smaller footprint (directly increasing circuit integration density and reducing cost per device).

### DETAILED DESCRIPTION OF THE INVENTION

The invention proposes new vertical p-(Mg)NiO/n-(Al)Ga2O3 bipolar diodes. The alloying with Al and Mg is introduced to adjust the already ultra WBG bandgaps of Ga2O3 and NiO, enhancing the capability to operate further into the UV and in self-powered photovoltaic mode. For power circuits, increased bandgaps enhance power management capability and improve suitability for use in harsh environments.

Indeed, thin layers of n-doped (Al)Ga2O3 and p-doped (Mg)NiO can form p-n junctions and, with the insertion of intrinsic interlayers (e.g., MgO), can form p-i-n junctions. Electrical properties can be adjusted by in situ doping control (via oxygen stoichiometry and/or Sn, Si, Li doping) and/or post-irradiation treatments. Bandgaps will be engineered by Al & Mg alloying, respectively.

This invention proposes the first p-n heterojunction of the two UWBG semiconductor oxides (Al)Ga2O3 n-doped and (Mg)NiO p-doped with modified band alignment and doping levels. Alloying and the addition of doping impurities pose challenges as they impact crystalline structure and surface/interface morphologies, via external impurity diffusion, segregation effects, surface diffusion, and surface energy considerations, all of which play an active role during growth. Other innovative aspects relate to: (a) better understanding and mastery of strain engineering in (and between) (Al)Ga2O3 and (Mg)NiO layers, (b) establishment of sharp interfaces for optimal device operation, (c) development and mastery of carrier transport modulation technologies based on modeling, in-situ doping/alloying, and ex-situ irradiation and/or post-treatment(s).

Epitaxial growth of ‘i-MgO’ requires continuous, pinhole-free, and extremely thin growth, several nanometers at most. This layer will also need to be electrically insulating.

### BEST MODE OF CARRYING OUT THE INVENTION

Fabrication of epitaxial (Al)Ga2O/(Mg)NiO and (Al)Ga2O/MgO/(Mg)NiO with appropriately tailored layer and interface properties. The device requires high crystalline quality, sharp interfaces, and electrical properties suited to targets (including reproducibly achieving very low carrier levels). Controlled n-type, p-type, and intrinsic doping of these materials is required to obtain functional materials suitable for power electronics, PE, applications.

The main challenge is to address interface properties for a specific bandgap composition while targeting “optimal” doping/activation levels and electrical characteristics.

Growth of epitaxial layers of (Al)Ga2O3, MgO, and (Mg)NiO with controlled bandgaps, high crystalline quality, smooth surface morphologies, and very low background carrier densities.

The n-AlGa2O3 and p-MgNiO will be doped with shallow impurities using, for example, Si [16], Sn [6], and Li [9, 15] respectively to modify the carrier concentration and Fermi level for appropriate band alignment and enhanced carrier injection. Layer and interface properties (crystalline structure, composition, thickness, conductivity, mobility, band alignment, and doping levels/gradients) are designed to provide suitable p-n heterojunction behavior for targeted applications [25][26].

Another major challenge is managing strains and band alignment at the interface due to surface/interface effects; i.e., local atomic rearrangement (which should be significant due to different crystalline structures and significant lattice mismatches between two material families) and corresponding charge transfer effects. Lattice mismatch as well as the presence of relatively high impurity concentrations (e.g., Al in Ga2O3 and Mg in NiO) can also lead to the formation of localized interface states that may impact, for example, electrical conductivity for a p-i-n junction configuration.

Control of n-type doping (Al)Ga2O3 (over a range of 1014 to 1019 cm-3) is necessary for managing the internal electric field. Control of p-type NiO doping (over the range of 1014-1019 cm-3) is necessary for managing the internal electric field. It is also possible to achieve MgNiO and AlGaO doping by irradiation or implantation.

### REFERENCE

[1] S. Reese, et al. “How much will gallium oxide power electronics cost?”, Joule 3(4), 903-907 (2019)
[2] L.M. Tolbert, et al., “Power electronics for distributed energy systems and utility-scale transmission and distribution applications: technical needs assessment for utility applications.” (Oak Ridge, TN: Oak Ridge National Laboratory, 2005)
[3] B. Reese et al. “Techno-economic analysis of Ga2O3 for WBG semiconductor market”, Proc. SPIE 11281OH (2020 )
[4] F. Zhang et al. Wide bandgap engineering of AlGa2O3 films Appl. Phys. Lett. 105, 162107
[5] Pérez, Rogers et al. WBG oxides: when PV meets transparent power electronics Proc SPIE 10533 (2018) 1Q1
[6] Higashiwaki et al. “Ga2O3 MESFETs on β-Ga2O3 (010) single crystalline substrates” Appl. Phys. Lett. 100, 013504(2012)
[7] M. Tadjer et al Theory and characterization of doping and defects in Ga2O3 ECS J. Solid State Sci Tech. 8 Q3187(2019)
[8] C.A. Niedermeier et al. Band gap bowing in NixMg1-xO Scientific Reports 6(1):31230(2016)
[9] S. Lany et al. Asymmetry in doping of oxides: NiO hole doping vs. ZnO electron doping Phys. Rev. B 75, 241203R (2007)
[10] Higashiwaki et al. Ga2O3 FETs in depletion-mode on β-Ga2O3 dependence & T Appl. Phys. Lett. 103, 123511(2013)
[11] Z. Cheng et al. Integration of Ga2O3 on Diamond for Thermal Management, Appl. Phys. Lett. 116, 062105(2020)
[12] Rogers et al. Chemical and laser lift-off for GaN transfer to alternative substrates Proc. SPIE 8626 (2013) 11-1
[13] Razeghi, Rogers et al Review of Growth, Doping & Applications of Ga2O3 thin films” Proc of SPIE 10533 (2018) 0R1
[14] Rogers et al Adjustable UVC selectivity and solar blindness in PLD Ga2O3 photodetectors Proc SPIE 11687 (2021) 2D1
[15] Sandana, Rogers et al. Thin-film p-type NiO-based FETs: PLD Li Proc. SPIE 10919(2019) 1H-1
[16] Sasaki Si-Ion Implantation Doping in Ga2O3 & Fabrication of Low-Resistance Ohmic Contacts Appl Phys Express 6 086502 (2013)
[17] Y. Lv et al. Demonstration of Schottky diodes with Ga2O3 junction barrier with a Baliga figure of merit of 0.85 GW/cm2 or handling capabilities of 5 A/700 V, IEEE Trans. Electron Devices. 36, 6179(2021)
[18] Yao, Davis, Robert & Porter, Inquiry into Different Metals as Ohmic Contacts with β-Ga2O3: Comparison and Analysis of Electrical Behavior, Morphology, and Other Physical Properties. Journal of Electronic Materials. 46. 10.1007/s11664-016-5121-1.
[19] Abou Daher et al AlGaN/GaN HEMTs on diamond by AlN bonding J Vac SciTechnol B 38 3 (2020) 033201
[20] X. Gonze et al, Computer Phys. Commun. 180, 2582-2615 (2009)
[21] http://www.bethe-salpeter.org.
[22] M.L. Trolle, et al., Sci. Rep. 7, 39844; doi: 10.1038/srep39844 (2017)
[23] Chikoidze Rogers et al Robust and puzzling 2D conductivity in undoped Ga2O3 films Mat TodayPhysics 8 (2019)
[24] Sandana, Rogers et al Study of transparent p-NiO/n-ZnO heterojunctions by PLD Proc SPIE 9364 (2015) 1O-1
[25] FH Teherani, D.J. Rogers, et al., “A study on the impact of sapphire substrate orientation on the properties of nominally undoped β-Ga2O3 thin films grown by pulsed laser deposition”. Proc. SPIE 10105, 101051R-1 (2017)
[26] V.E. Sandana et al. Growth of NiO on Si (111), c-Al2O3 & FTO/Glass by PLD, Proc. SPIE 8987, 89872P-1 (2014)
[27] T.-Dang et al., Effect of high-energyelectron irradiation on Ga2O3 electronic properties, Proc SPIE 1200207(2022) [28] De France, Fabrication/Characterization/Analysis of AlGaN/GaN HEMTs on Flexible Substrates IEEE Trans Elec Dev 60 3 2013
[29] Kubsky et al. “Analysis of the local composition of SIC microstructures formed by ion projection into Si using energy-filtered TEM in combination with FIB sample preparation” J. Mat. Sci. Ing. B, Vol 102, I 1-3, 2003, p. 70-74
[30] Scheiderer et al. Materials for Mottronics: Excessive O doping of the prototypical Mott insulator Adv. Tapis. 30 1706708 201 8

1. A vertical heterojunction bipolar or PIN diode comprising:
heterostructures between ternary alloys (Mg)NiO and (Al)Ga2O3 or (Mg)NiO/i-MgO/(Al)Ga2O3 or (Mg)NiO/Al2O3/(Al)Ga2O3;
wherein the (Mg)NiO is p-type, the (Al)Ga2O3 is n-type and the intrinsic layer is MgO or Al2O3; and
wherein the bandgaps of Ga2O3 and NiO have been increased by alloys with Al and/or Mg to appropriately design the alignment of said bandgaps and to optimize carrier injection to enable more efficient diode operation, operation of a photodetector at shorter wavelengths, and operation of power electronics at higher voltages.

2. The vertical heterojunction bipolar or PIN diode according to claim 1 wherein n-AlGa2O3 being is doped with shallow impurities, using Si or Sn and p-MgNiO is doped with shallow impurities using Li so as to design the carrier concentration and Fermi level for an enhanced and more efficient bandgap alignment and carrier injection.

3. The vertical heterojunction bipolar or PIN diode according to claim 1 wherein tailored and controlled growth of continuous 2D MgO layers with i-doping allows for managing the internal electric field.

4. The vertical heterojunction bipolar or PIN diode according to claim 1, wherein the growth of n-type (Al)Ga2O3, p-type (Mg)NiO, and intrinsic MgO and Al2O3 is performed by epitaxy, namely: molecular beam epitaxy (MBE) or atomic layer epitaxy (ALD) or metal-organic chemical vapor deposition (MOCVD) or hydride vapor phase epitaxy (HVPE) or sputtering (diode and rf) or pulsed laser deposition (PLD) or electron beam (or ion) deposition.

5. The vertical heterojunction bipolar or PIN diode according to claim 1 wherein the adapted and controlled growth of n-type doping of (Al)Ga2O3, and p-type doping of (Mg)NiO is in a range of 1014 to 1020/cm-3 to optimize component performance and enable management of the internal electric field.

6. The vertical heterojunction bipolar or PIN diode according to claim 1 whose electrical properties can be adjusted by in situ doping control, by controlling the oxygen proportion and/or by doping with Sn, Si, Li and/or by post-irradiation and/or thermal treatments, so as to obtain a concentration and Fermi level for enhanced and more efficient bandgap alignment and carrier injection.

7. The vertical heterojunction bipolar or PIN diode according to claim 1 used in power electronics or UVC photodetection.
